(19) United States
(12) Patent Application Publication
(10) Pub. No.: US 2001/0052104 A1
(43) Pub. Date: Dec. 13, 2001

(54) Iteration terminating using quality index criteria of turbo codes

(75) Inventors: Shuzhan J. Xu, Franklin Park, NJ (US); Wayne Stark, Ann Arbor, MI (US)

Correspondence Address: Motorola, Inc., Intellectual Property Dept. (BMM), 600 North US Highway 45, AN475, Libertyville, IL, 60048, US

(73) Assignee: Motorola, Inc.

(21) Appl. No.: 09/802,828

(22) Filed: Mar. 9, 2001

Related U.S. Application Data
(63) Continuation-in-part of application No. 09/553,646, filed on Apr. 20, 2000.

(51) Int. Cl. H03M 13/25

(52) U.S. Cl. 714/792

(57) ABSTRACT

A decoder dynamically terminates iteration calculations in the decoding of a received convolutionally coded signal using local quality index criteria. In a turbo decoder with two recursion processors connected in an iterative loop, at least one additional recursion processor is coupled in parallel at the inputs of at least one of the recursion processors. All of the recursion processors perform concurrent iterative calculations on the signal. The at least one additional recursion processor calculates a local quality index of a moving average of extrinsic information for each iteration over a portion of the signal. A controller terminates the iterations when the measure of the local quality index is less than a predetermined threshold, and requests a retransmission of the portion of the signal.

### CROSS REFERENCE TO RELATED APPLICATIONS

This application is a continuation-in-part of U.S. patent application Ser. No. 09/553,646 by inventors Xu et al., which is assigned to the assignee of the present application, and is hereby incorporated herein in its entirety by this reference thereto.

### FIELD OF THE INVENTION

This invention relates generally to communication systems, and more particularly to a decoder for use in a receiver of a convolutionally coded communication system.

### BACKGROUND OF THE INVENTION

Convolutional codes are often used in digital communication systems to protect transmitted information from error. Such communication systems include the Direct Sequence Code Division Multiple Access (DS-CDMA) standard IS-95 and the Global System for Mobile Communications (GSM). Typically in these systems, a signal is convolutionally coded into an outgoing code vector that is transmitted. At a receiver, a practical soft-decision decoder, such as a Viterbi decoder as is known in the art, uses a trellis structure to perform an optimum search for the maximum likelihood transmitted code vector.

More recently, turbo codes have been developed that outperform conventional coding techniques. Turbo codes are generally composed of two or more convolutional codes and turbo interleavers. Turbo decoding is iterative and uses a soft output decoder to decode the individual convolutional codes. The soft output decoder provides information on each bit position which helps the soft output decoder decode the other convolutional codes. The soft output decoder is usually a MAP (maximum a posteriori) or soft output Viterbi algorithm (SOVA) decoder.

Turbo coding is efficiently utilized to correct errors in the case of communicating over an added white Gaussian noise (AWGN) channel. Intuitively, there are a few ways to examine and evaluate the error correcting performance of the turbo decoder. One observation is that the magnitude of log-likelihood ratio (LLR) for each information bit in the iterative portion of the decoder increases as iterations go on. This improves the probability of the correct decisions. The LLR magnitude increase is directly related to the number of iterations in the turbo decoding process. However, it is desirable to reduce the number of iterations to save calculation time and circuit power. The appropriate number of iterations (stopping criteria) for a reliably turbo decoded block varies as the quality of the incoming signal and the resulting number of errors incurred therein. In other words, the number of iterations needed is related to channel conditions, where a more noisy environment will need more iterations to correctly resolve the information bits and reduce error.

One prior art stopping criteria utilizes a parity check as an indicator to stop the decoding process. A parity check is straightforward as far as implementation is concerned. However, a parity check is not reliable if there are a large number of bit errors. Another type of criteria for the turbo decoding iteration stop is the LLR (log-likelihood-ratio) value as calculated for each decoded bit. Since turbo decoding converges after a number of iterations, the LLR of a data bit is the most direct indicator index for this convergence. One way this stopping criteria is applied is to compare LLR magnitude to a certain threshold. However, it can be difficult to determine the proper threshold as channel conditions are variable. Still other prior art stopping criteria measure the entropy or difference of two probability distributions, but this requires much calculation.

There is a need for a decoder that can determine the appropriate stopping point for the number of iterations of the decoder in a reliable manner. It would also be of benefit to provide the stopping criteria without a significant increase in calculation complexity. Further, it would be beneficial to provide retransmit criteria to improve bit error rate performance.

### BRIEF DESCRIPTION OF THE DRAWINGS

FIG. 1 shows a trellis diagram used in soft output decoder techniques as are known in the prior art;

FIG. 2 shows a simplified block diagram for turbo encoding as is known in the prior art;

FIG. 3 shows a simplified block diagram for a turbo decoder as is known in lo the prior art;

FIG. 4 shows a simplified block diagram for a turbo decoder with an iterative quality index criteria, in accordance with the present invention;

FIG. 5 shows simplified block diagram for the Viterbi decoder as used in FIG. 4; and

FIG. 6 shows a flowchart for a method for turbo decoding, in accordance with the present invention.

### DETAILED DESCRIPTION OF THE PREFERRED EMBODIMENT

The present invention provides a turbo decoder that dynamically utilizes the virtual (intrinsic) SNR as a quality index stopping criteria and retransmit criteria of the in-loop data stream at the input of each constituent decoder stage, as the loop decoding iterations proceed. A (global) quality index is used as a stopping criteria to determine the number of iterations needed in the decoder, and a local quality index is used to request a retransmission when necessary. Advantageously, by limiting the number of calculations to be performed in order to decode bits reliably, the present invention conserves power in the communication device and saves calculation complexity.

Typically, block codes, convolutional codes, turbo codes, and others are graphically represented as a trellis as shown in FIG. 1, wherein a four state, five section trellis is shown. For convenience, we will reference M states per trellis section (typically M equals eight states) and N trellis sections per block or frame (typically N=5000). Maximum a posteriori type decoders (log-MAP, MAP, max-log-MAP, constant-log-MAP, etc.) utilize forward and backward generalized Viterbi recursions or soft output Viterbi algorithms (SOVA) on the trellis in order to provide soft outputs at each section, as is known in the art. The MAP decoder minimizes the decoded bit error probability for each information bit based on all received bits.

Because of the Markov nature of the encoded sequence (wherein previous states cannot affect future states or future output branches), the MAP bit probability can be broken into the past (beginning of trellis to the present state), the present state (branch metric for the current value), and the future (end of trellis to current value). More specifically, the MAP decoder performs forward and backward recursions up to a present state wherein the past and future probabilities are used along with the present branch metric to generate an output decision. The principles of providing hard and soft output decisions are known in the art, and several variations of the above described decoding methods exist. Most of the soft input-soft output (SISO) decoders considered for turbo codes are based on the prior art optimal MAP algorithm in a paper by L. R. Bahl, J. Cocke, F. Jelinek, and J. Raviv entitled “Optimal Decoding of Linear Codes for Minimizing Symbol Error Rate”, IEEE Transactions on Information Theory, Vol. IT-20, March 1974, pp. 284-7 (BCJR algorithm).

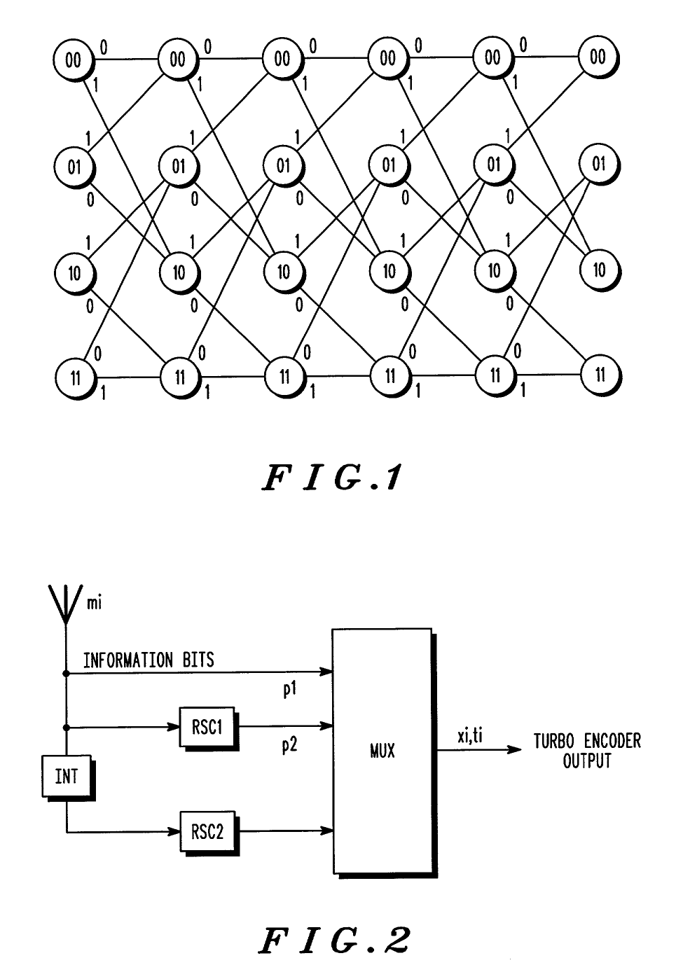

FIG. 2 shows a typical turbo coder that is constructed with interleavers and constituent codes which are usually systematic convolutional codes, but can be block codes also. In general, a turbo encoder is a parallel concatenation of two recursive systemic convolutional encoders (RSC) with an interleaver (int) between them. The output of the turbo encoding is generated by multiplexing (concatenating) the information bits mᵢ and the parity bits pᵢ from the two encoders, RSC1 and RSC2. Optionally, the parity bits can be punctured as is known in the art to increase code rate (i.e., a throughput of ½). The turbo encoded signal is then transmitted over a channel. Noise, nᵢ, due to the AWGN nature of the channel becomes added to the signal, xₗ, during transmission. The noise variance of the AWGN can be expressed as σ²=Nₒ/2, where Nₒ/2 is the two sided noise power spectrum density. The noise increases the likelihood of bit errors when a receiver attempts to decode the input signal, yₗ(=xᵢ+nₗ), to obtain the original information bits mᵢ. Correspondingly, noise affects the transmitted parity bits to provide a signal tₗ=pₗ+nₗ.

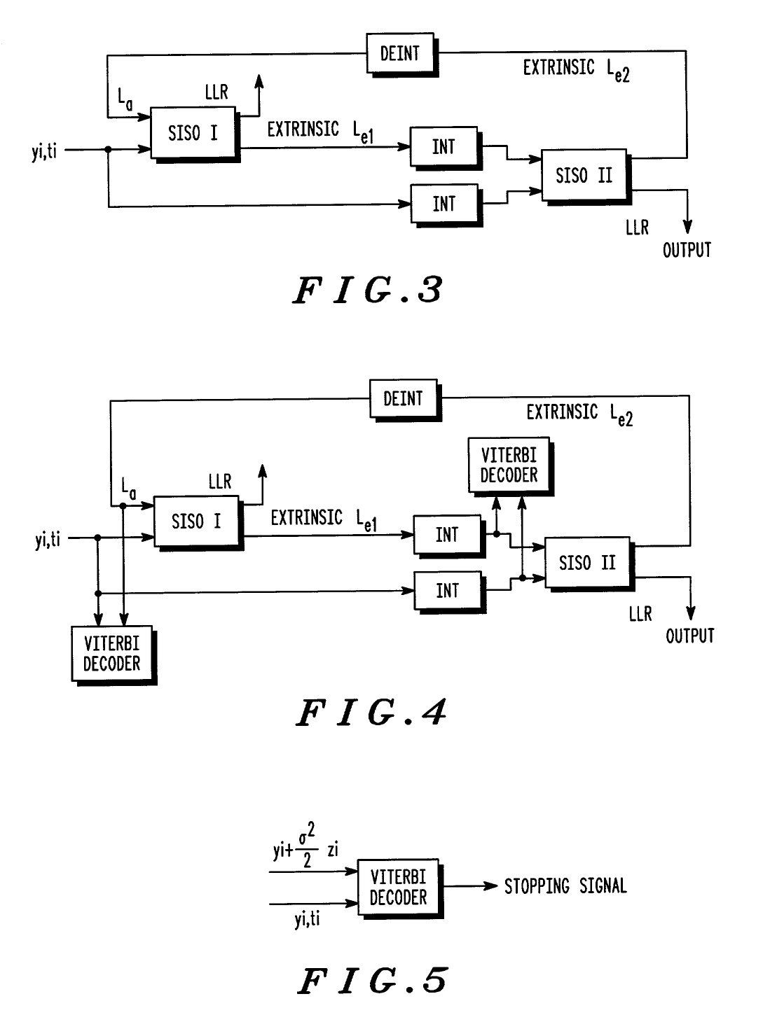

FIG. 3 shows a typical turbo decoder that is constructed with interleavers, de-interleavers, and decoders. The mechanism of the turbo decoder regarding extrinsic information Lₑ₁, Lₑ₂, interleaver (int), de-interleaver (deint), and the iteration process between the soft-input, soft-output decoder sections SISO1 and SISO2 follow the Bahl algorithm. Assuming zero decoder delay in the turbo decoder, the first decoder (SISO1) computes a soft output from the input signal bits, yᵢ, and the a priori information (Lₐ), which will be described below. The soft output is denoted as Lₑ₁, for extrinsic data from the first decoder. The second decoder (SISO2) is input with interleaved versions of Lₑ₁ (the a priori information from Lₐ), the input signal bits yᵢ. The second decoder generates extrinsic data, Lₑ₂, which is deinterleaved to produce Lₐ which is fed back to the first decoder, and a soft output (typically a MAP LLR) provide a soft output of the original information bits mᵢ. Typically, the above iterations are repeated for a fixed number of times (usually sixteen) for each bit until all the input bits are decoded.

MAP algorithms minimize the probability of error for an information bit given the received sequence, and they also provide the probability that the information bit is either a 1 or 0 given the received sequence. The prior art BCJR algorithm provides a soft output decision for each bit position (trellis section of FIG. 1) wherein the influence of the soft inputs within the block is broken into contributions from the past (earlier soft inputs), the present soft input, and the future (later soft inputs). The BCJR decoder algorithm uses a forward and a backward generalized Viterbi recursion on the trellis to arrive at an optimal soft output for each trellis section (stage). These a posteriori probabilities, or more commonly the log-likelihood ratio (LLR) of the probabilities, are passed between SISO decoding steps in iterative turbo decoding. The LLR for each information bit is

$${La}_{k} = ln \frac{{\sum }_{( m , n ) ∈ {B}^{1}} {α}_{k - 1} ( n ) {γ}_{k} ( n , m ) {β}_{k} ( m )}{{\sum }_{( m , n ) ∈ {B}^{0}} {α}_{k - 1} ( n ) {γ}_{k} ( n , m ) {β}_{k} ( m )} , \qquad ( 1 )$$

for all bits in the decoded sequence (k=1 to N). In equation (1), the probability that the decoded bit is equal to 1 (or 0) in the trellis given the received sequence is composed of a product of terms due to the Markov property of the code. The Markov property states that the past and the future are independent given the present. The present, γₖ(n,m), is the probability of being in state m at time k and generating the symbol γₖ when the previous state at time k−1 was n. The present plays the function of a branch metric. The past, αᵢ(m), is the probability of being in state m at time k with the received sequence {y₁, . . . , yₖ}, and the future, βₖ(m), is the probability of generating the received sequence {yₖ₊₁, . . . , y_{N}} from state m at time k. The probability αₖ(m) can be expressed as function of αₖ₋₁(m) and γₖ(n,m) and is called the forward recursion

$${α}_{k} ( m ) = {\sum }_{n = 0}^{M - 1} {α}_{k - 1} ( n ) {γ}_{k} ( n , m ) m = 0 , … , M - 1 , \qquad ( 2 )$$

where M is the number of states. The reverse or backward recursion for computing the probability βₖ(n) from βₖ₊₁(n) and γₖ(n,m) is

$${β}_{k} ( n ) = {\sum }_{m = 0}^{M - 1} {β}_{k + 1} ( m ) {γ}_{k} ( n , m ) n = 0 , … , M - 1. \qquad ( 3 )$$

The overall a posteriori probabilities in equation (2) are computed by summing over the branches in the trellis B¹ (B⁰) that correspond to the information bit being 1 (or 0).

The LLR in equation (1) requires both the forward and reverse recursions to be available at time k. In general, the BCJR method for meeting this requirement is to compute and store the entire reverse recursion using a fixed number of iterations, and recursively compute αₖ(m) and Laₖ from k=1 to k=N using αₖ₋₁ and βₖ.

The performance of turbo decoding is affected by many factors. One of the key factors is the number of iterations. As a turbo decoder converges after a few iterations, more iterations after convergence will not increase performance significantly. Turbo codes will converge faster under good channel conditions requiring a fewer number of iterations to obtain good performance, and will diverge under poor channel conditions. The number of iterations performed is directly proportional to the number of calculations needed and it will affect power consumption. Since power consumption is of great concern in the mobile and portable radio communication devices, there is an even higher emphasis on finding reliable and good iteration stopping criteria. Motivated by these reasons, the present invention provides an adaptive scheme for stopping the iteration process and for providing retransmit criteria.

In the present invention, the number of iterations is defined as the total number of SISO decoding stages used (i.e. two iterations in one cycle). Accordingly, the iteration number counts from 0 to 2N−1. Each decoding stage can be either MAP or SOVA. The key factor in the decoding process is to combine the extrinsic information into a SISO block. The final hard decision on the information bits is made according to the value of the LLR after iterations are stopped. The final hard bit decision is based on the LLR polarity. If the LLR is positive, decide +1, otherwise decide −1 for the hard output.

In the present invention, the in-loop signal-to-noise ratio (intrinsic SNR) is used as the iteration stopping criterion in the turbo decoder. Since SNR improves when more bits are detected correctly per iteration, the present invention uses a detection quality indicator that observes the increase in signal energy relative to the noise as iterations go on.

FIG. 4 shows a turbo decoder with at least one additional Viterbi decoder to monitor the decoding process, in accordance with the present invention. Although one Viterbi decoder can be used, two decoders give the flexibility to stop iterations at any SISO decoder. The Viterbi decoders are used because it is easy to analyze the Viterbi decoder to get the quality index. The Viterbi decoder is just used to do the mathematics in the present invention, i.e. to derive the quality indexes and intrinsic SNR values. No real Viterbi decoding is needed. It is well known that MAP or SOVA will not outperform the conventional Viterbi decoder significantly if no iteration is applied. Therefore, the quality index also applies towards the performance of MAP and SOVA decoders. The error due to the Viterbi approximation to SISO (MAP or SOVA) will not accumulate since there is no change in the turbo decoding process itself. Note that the turbo decoding process remains as it is. The at least one additional Viterbi decoder is attached for analysis to generate the quality index and no decoding is actually needed.

In a preferred embodiment, two Viterbi decoders are used. In practice, where two identical RSC encoder are used, thus requiring identical SISO decoders, only one Viterbi decoder is needed, although two of the same decoders can be used. Otherwise, the two Viterbi decoders are different and they are both required. Both decoders generate extrinsic information for use in an iteration stopping signal, and they act independently such that either decoder can signal a stop to iterations. The Viterbi decoders are not utilized in the traditional sense in that they are only used to do the mathematics and derive the quality indexes and intrinsic SNR values. In addition, since iterations can be stopped mid-cycle at any SISO decoder, a soft output is generated for the transmitted bits from the LLR of the decoder where the iteration is stopped.

The present invention utilizes the extrinsic information available in the iterative loop in the Viterbi decoder. For an AWGN channel, we have the following path metrics with the extrinsic information input:

$$p [ Y \vert X ] = {\prod }_{i = 0}^{L - 1} p [ {y}_{i} \vert {x}_{i} ] p [ {t}_{i} \vert {p}_{i} ] p [ {m}_{i} ]$$

where mᵢ is the transmitted information bit, xₗ=mₗ is the systematic bit, and pₗ is the parity bit. With mₗ in polarity form (1→+1 and 0→−1), we rewrite the extrinsic information as

$$p [ {m}_{i} ] = \frac{{ⅇ}^{{z}_{i}}}{1 + {ⅇ}^{{z}_{i}}} = \frac{{ⅇ}^{{z}_{i} / 2}}{{ⅇ}^{- {z}_{i} / 2} + {ⅇ}^{{z}_{i} / 2}} , if {m}_{i} = + 1$$

$$p [ {m}_{i} ] = \frac{1}{1 + {ⅇ}^{{z}_{i}}} = \frac{{ⅇ}^{- {z}_{i} / 2}}{{ⅇ}^{- {z}_{i} / 2} + {ⅇ}^{{z}_{i} / 2}} , if {m}_{i} = - 1$$

p[mᵢ] is the a priori information about the transmitted bits,

$${z}_{i} = log \frac{p [ {m}_{i} = + 1 ]}{p [ {m}_{i} = - 1 ]}$$

is the extrinsic information, or in general,

$$p [ {m}_{i} ] = \frac{{ⅇ}^{{m}_{i} {z}_{i} / 2}}{{ⅇ}^{- {z}_{i} / 2} + {ⅇ}^{{z}_{i} / 2}}$$

The path metric is thus calculated as

$$\begin{matrix}p [ Y \vert X ] = {\prod }_{i = 0}^{L - 1} p [ {y}_{i} \vert {x}_{i} ] p [ {t}_{i} \vert {p}_{i} ] [ {m}_{i} ] \\ = {( \frac{1}{\sqrt{2 π} σ} )}^{L} {ⅇ}^{\frac{1}{2 {σ}^{2}} {\sum }_{i = 0}^{L - 1} \{ {( {x}_{i} - {y}_{i} )}^{2} + {( {p}_{i} - {t}_{i} )}^{2} \}} \\ = ( {\prod }_{i = 0}^{L - 1} \frac{1}{{ⅇ}^{- {z}_{i} / 2} + {ⅇ}^{{z}_{i} / 2}} ) {ⅇ}^{\frac{1}{2} {\sum }_{i = 0}^{L - 1} {m}_{i} {z}_{i}}\end{matrix}$$

Note that

$${ⅇ}^{\frac{1}{2} {\sum }_{i = 0}^{L - 1} {m}_{i} {z}_{i}}$$

is the correction factor introduced by the extrinsic information. And from the Viterbi decoder point of view, this correcting factor improves the path metric and thus improves the decoding performance. This factor is the improvement brought forth by the extrinsic information. The present invention introduces this factor as the quality index and the iteration stopping criteria and retransmit criteria for turbo codes.

In particular, for iteration stopping the turbo decoding (global) quality index Q(iter,{mₗ},L) is:

$$Q ( iter , \{ {m}_{i} \} , L ) = {\sum }_{i = 0}^{L - 1} {m}_{i} {z}_{i}$$

where iter is the iteration number, L denote number of bits in each decoding block, mₗ is the transmitted information bit, and zₗ is the extrinsic information generated after each small decoding step. More generally,

$$Q ( iter , \{ {m}_{i} \} , \{ {w}_{i} \} , L ) = {\sum }_{i = 0}^{L - 1} {w}_{i} {m}_{i} {z}_{i}$$

where wᵢ is a weighting function to alter performance. In a preferred embodiment, wᵢ is a constant of 1.

This index remains positive since typically zₗ and mₗ have the same polarity. In practice, the incoming data bits {mₗ} are unknown, and the following index is used instead:

$${Q}_{H} ( iter , \{ {m}_{i} \} , L ) = {\sum }_{i = 0}^{L - 1} {\hat{d}}_{i} {z}_{i}$$

where \hat{d}ₗ is the hard decision as extracted from the LLR information. That is \hat{d}ₗ=sign {Lₗ} with Lₗ denoting the LLR value. The following soft output version of the quality index can also be used for the same purpose:

$${Q}_{S} ( iter , \{ {m}_{i} \} , L ) = {\sum }_{i = 0}^{L - 1} {L}_{i} {z}_{i} or more generally$$

$${Q}_{S} ( iter , \{ {m}_{i} \} , \{ {w}_{i} \} , L ) = {\sum }_{i = 0}^{L - 1} {w}_{i} {L}_{i} {z}_{i}$$

Note that these indexes are extremely easy to generate and require very little hardware. In addition, these indexes have virtually the same asymptotic behavior and can be used as a good quality index for the turbo decoding performance evaluation and iteration stopping criterion.

The behavior of these indexes is that they increase very quickly for the first a few iterations and then they approach an asymptote of almost constant value. This asymptotic behavior describes the turbo decoding process well and serves as a quality monitor of the turbo decoding process. In operation, the iterations are stopped if this index value crosses the knee of the asymptote.

The iterative loop of the turbo decoder increases the magnitude of the LLR such that the decision error probability will be reduced. Another way to look at it is that the extrinsic information input to each decoder is virtually improving the SNR of the input sample streams. The following analysis is presented to show that what the extrinsic information does is to improve the virtual SNR to each constituent decoder. This helps to explain how the turbo coding gain is reached. Analysis of the incoming samples is also provided with the assistance of the Viterbi decoder as described before.

The path metric equation of the attached additional Viterbi decoders is

$$p [ Y \vert Z ] = {( \frac{1}{\sqrt{2 π} σ} )}^{L} {ⅇ}^{- \frac{1}{2 {σ}^{2}} {\sum }_{i = 0}^{L - 1} \{ {( {x}_{i} - {y}_{i} )}^{2} + {( {p}_{i} - {t}_{i} )}^{2} \}} ( {\prod }_{i = 0}^{L - 1} \frac{1}{{ⅇ}^{- {z}_{i} / 2} + {ⅇ}^{{z}_{i} / 2}} ) {ⅇ}^{\frac{1}{2} {\sum }_{i = 0}^{L - 1} {m}_{i} {z}_{i}}$$

Expansion of this equation gives

$$\begin{matrix}p [ Y \vert X ] = {( \frac{1}{\sqrt{2 π} σ} )}^{2 L} ( {\prod }_{i = 0}^{L - 1} \frac{1}{{ⅇ}^{- {z}_{i}} + {ⅇ}^{{z}_{i} / 2}} ) \cdot \\ {ⅇ}^{- \frac{1}{2 {σ}^{2}} {\sum }_{i = 0}^{L - 1} ( {x}_{i}^{2} + {y}_{i}^{2} )} {ⅇ}^{- \frac{1}{2 {σ}^{2}} {\sum }_{i = 0}^{L - 1} ( {t}_{i}^{2} + {p}_{i}^{2} )} {ⅇ}^{\frac{1}{2 {σ}^{2}} {\sum }_{i = 0}^{L - 1} ( 2 {x}_{i} {y}_{i} + 2 {t}_{i} {p}_{i} )} {ⅇ}^{\frac{1}{2} {\sum }_{i = 0}^{L - 1} {x}_{i} {z}_{i}} \\ = {( \frac{1}{\sqrt{2 π} σ} )}^{2 L} ( {\prod }_{i = 0}^{L - 1} \frac{1}{{ⅇ}^{- {z}_{i} / 2} + {ⅇ}^{{z}_{i} / 2}} ) \cdot \\ {ⅇ}^{- \frac{1}{2 {σ}^{2}} {\sum }_{i = 0}^{L - 1} ( {x}_{i}^{2} + {y}_{i}^{2} )} {ⅇ}^{- \frac{1}{2 {σ}^{2}} {\sum }_{i = 0}^{L - 1} ( {t}_{i}^{2} + {p}_{i}^{2} )} {ⅇ}^{\frac{1}{{σ}^{2}} {\sum }_{i = 0}^{L - 1} ( {x}_{i} {y}_{i} + {t}_{i} {p}_{i} ) + \frac{1}{2} {\sum }_{i = 0}^{L - 1} {x}_{i} {z}_{i}}\end{matrix}$$

Looking at the correlation term, we get the following factor

$$\begin{matrix}\frac{1}{{σ}^{2}} {\sum }_{i = 0}^{L - 1} ( {x}_{i} {y}_{i} + \frac{{σ}^{2}}{2} {x}_{i} {z}_{i} ) + \frac{1}{{σ}^{2}} {\sum }_{i = 0}^{L - 1} {t}_{i} {p}_{i} = \frac{1}{{σ}^{2}} {\sum }_{i = 0}^{L - 1} {x}_{i} ( {y}_{i} + \frac{{σ}^{2}}{2} {z}_{i} ) + \frac{1}{{σ}^{2}} {t}_{i} {p}_{i} \\ = \frac{1}{{σ}^{2}} {\sum }_{i = 0}^{L - 1} \{ {x}_{i} ( {y}_{i} + \frac{{σ}^{2}}{2} {z}_{i} ) + {t}_{i} {p}_{i} \}\end{matrix}$$

For the Viterbi decoder, to search for the minimum Euclidean distance is the same process as searching for the following maximum correlation.

$$\frac{1}{{σ}^{2}} {\sum }_{i = 0}^{L - 1} \{ {x}_{i} ( {y}_{i} + \frac{{σ}^{2}}{2} {z}_{i} ) + {t}_{i} {p}_{i} \}$$

or equivalently, the input data stream to the Viterbi decoder is

$$\{ ( {y}_{i} + \frac{{σ}^{2}}{2} {z}_{i} ) , {t}_{i} ) \} ,$$

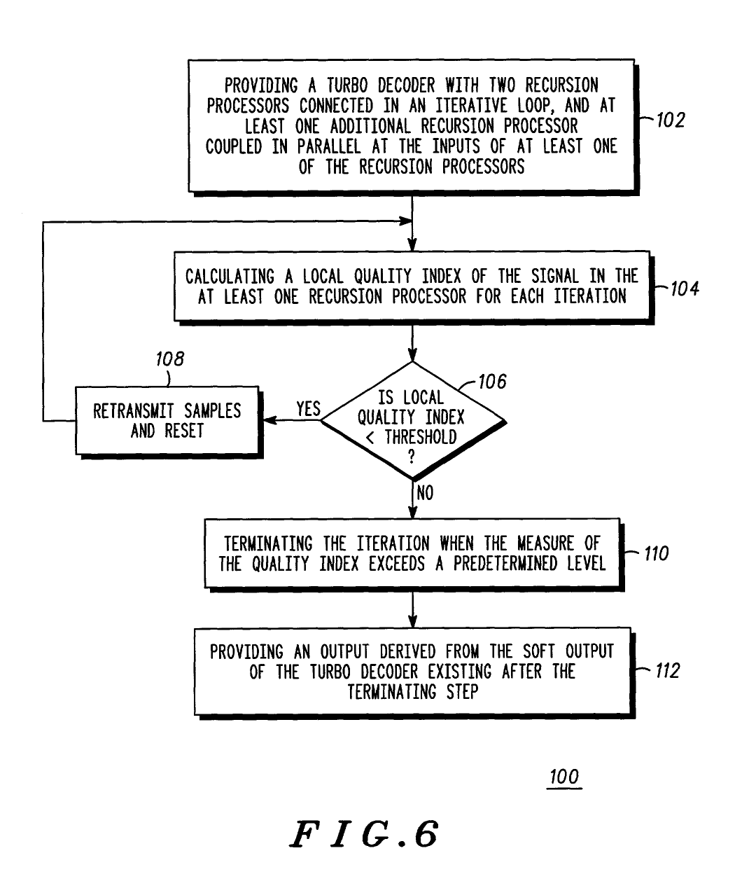

which is graphically depicted in FIG. 5.

Following the standard signal-to-noise ratio calculation formula

$$SNR = \frac{{( E [ {y}_{i} \vert {x}_{i} ] )}^{2}}{{σ}^{2}}$$

and given the fact that yₗ=xᵢ+nᵢ and tₗ=pᵢ+nₗ (where pₗ are the parity bits of the incoming signal), we get SNR for the input data samples into the constituent decoder as

$$\begin{matrix}SNR ( {x}_{i} , {y}_{t} , iter ) = \frac{{( E [ {y}_{i} + \frac{{σ}^{2}}{2} {z}_{i} \vert {x}_{t} ] )}^{2}}{{σ}^{2}} \\ = \frac{{( E [ {x}_{i} + {n}_{i} + \frac{{σ}^{2}}{2} {z}_{i} \vert {x}_{i} ] )}^{2}}{{σ}^{2}} \\ = \frac{{( {x}_{i} + \frac{{σ}^{2}}{2} {z}_{i} )}^{2}}{{σ}^{2}} \\ = \frac{{x}_{i}^{2}}{{σ}^{2}} + {x}_{i} {z}_{i} + \frac{{σ}^{2}}{4} {z}_{i}^{2}\end{matrix}$$

Notice that the last two terms are correction terms due to the extrinsic information input. The SNR for the input parity samples are

$$SNR ( {p}_{i} , {t}_{i} , iter ) = \frac{{( E [ {t}_{i} \vert {p}_{t} ] )}^{2}}{{σ}^{2}} = \frac{{( E [ {p}_{i} + {n}_{i}^{2} \vert {p}_{i} l ] )}^{2}}{{σ}^{2}} = \frac{{p}_{i}^{2}}{{σ}^{2}}$$

Now it can be seen that the SNR for each received data samples are changing as iterations go on because the input extrinsic information will increase the virtual or intrinsic SNR. Moreover, the corresponding SNR for each parity sample will not be affected by the iteration. Clearly, if xₗ has the same sign as zₗ, we have

$$SNR ( {x}_{i} , {y}_{i} , iter ) = \frac{{( {x}_{i} + \frac{{σ}^{2}}{2} {z}_{i} )}^{2}}{{σ}^{2}} \geq \frac{{x}_{i}^{2}}{{σ}^{2}} = SNR ( {x}_{i} , {y}_{i} , iter = 0 )$$

This shows that the extrinsic information increased the virtual SNR of the data stream input to each constituent decoder.

The average SNR for the whole block is

$$\begin{matrix}AverageSNR ( iter ) = \frac{1}{2 L} \{ {\sum }_{i = 0}^{L - 1} SNR ( {x}_{i} , {y}_{i} , iter ) + {\sum }_{i = 0}^{L - 1} SNR ( {p}_{i} , {t}_{i} , iter ) \} \\ = \frac{1}{2 L} \{ {\sum }_{i = 0}^{L - 1} \frac{{x}_{i}^{2}}{{σ}^{2}} + {\sum }_{i = 1}^{L - 1} \frac{{p}_{i}^{2}}{2 L} \} + \frac{1}{2 L} \{ {\sum }_{i = 0}^{L - 1} {x}_{i} {z}_{i} + \frac{{σ}^{2}}{4} {\sum }_{i = 0}^{L - 1} {z}_{i}^{2} ) \\ = AverageSNR ( 0 ) = \frac{1}{2 L} Q ( iter , \{ m \} , L ) + \frac{{σ}^{2}}{4} ( \frac{1}{2 L} {\sum }_{i = 0}^{L - 1} {z}_{i}^{2} )\end{matrix}$$

at each iteration stage.

If the extrinsic information has the same sign as the received data samples and if the magnitudes of the zₗ samples are increasing, the average SNR of the whole block will increase as the number of iteration increases. Note that the second term is the original quality index, as described previously, divided by the block size. The third term is directly proportional to the average of magnitude squared of the extrinsic information and is always positive. This intrinsic SNR expression will have the similar asymptotic behavior as the previously described quality indexes and can also be used as decoding quality indicator. Similar to the quality indexes, more practical intrinsic SNR values are:

$${AverageSNR}_{H} ( iter ) = StartSNR + \frac{1}{2 L} {Q}_{H} ( iter , \{ {m}_{i} \} , L ) + \frac{{σ}^{2}}{4} ( \frac{1}{2 L} {\sum }_{i = 0}^{L - 1} {z}_{i}^{2} ) ,$$

or a corresponding soft copy of it

$${AverageSNR}_{S} ( iter ) = StartSNR + \frac{1}{2 L} {Q}_{S} ( iter , \{ {m}_{i} \} , L ) + \frac{{σ}^{2}}{4} ( \frac{1}{2 L} {\sum }_{i = 0}^{L - 1} {z}_{i}^{2} )$$

where StartSNR denotes the initial SNR value that starts the decoding iterations. Optionally, a weighting function can be used here as well. Only the last two terms are needed to monitor the decoding quality. Note also that the normalization constant in the previous intrinsic SNR expressions has been ignored.

The above global quality index results from a summation across an entire decoding block of L bits, i.e. a summation over the range i=0 to L−1, to calculate the global quality index. In order to further computational savings, a second embodiment of the present invention envisions a local quality index that can be defined over a portion of the bits in the block, without sacrificing accuracy. The above intrinsic SNR calculation can also be used for the local quality index. In addition, a local quality index such as a Yamamoto and Itoh type of index is a useful generalization of the above global quality index based on Viterbi decoder analysis. For example, a local quality index can be defined as

$$Q ( \{ {m}_{i} \} , K ) = \frac{1}{N \sqrt{{E}_{b}}} {\sum }_{i ∈ K} {m}_{i} {z}_{i}$$

where zₗ is the extrinsic information, E_{b} is the energy per bit, K is a set of consecutive sample indexes in a frame and N is the number of indexes in it. For practical use, a hard index is defined

$${Q}_{H} ( \{ {m}_{i} \} , K ) = \frac{1}{N \sqrt{{E}_{b}}} {\sum }_{i ∈ K} {\hat{d}}_{i} {z}_{i}$$

where \hat{d}ₗ is the hard decision as \hat{d}ₗ=sign {Lᵢ}, and soft index is defined

$${Q}_{S} ( \{ {m}_{i} \} , K ) = \frac{1}{N \sqrt{{E}_{b}}} {\sum }_{i ∈ K} {L}_{i} {z}_{i}$$

as approximations. Since zₗ typically has same sign as mₗ

$${Q}_{a bs} ( \{ {m}_{i} \} , K ) = \frac{1}{N \sqrt{{E}_{b}}} {\sum }_{i ∈ K} \vert {z}_{i} \vert$$

can be used as local quality index, too. Similar to the intrinsic SNR previously described, the following local average virtual SNR value

$$AverageSNR ( 1 , K ) = StartSNR + \frac{1}{2} Q ( \{ {m}_{i} \} , K ) + \frac{{σ}^{2}}{4 {E}_{b}} ( \frac{1}{2 N} {\sum }_{i ∈ K} {z}_{i}^{2} )$$

can be used for the decoding stage. Correspondingly, the following practical virtual SNR values follow:

$${AverageSNR}_{H} ( 1 , K ) = StartSNR + \frac{1}{2} {Q}_{H} ( \{ {m}_{i} \} , K ) + \frac{{σ}^{2}}{4 {E}_{b}} ( \frac{1}{2 N} {\sum }_{i ∈ K} {Z}_{i}^{2} )$$

using the hard decision or

$${AverageSNR}_{S} ( 1 , K ) = StartSNR + \frac{1}{2} {Q}_{S} ( \{ {m}_{i} \} , K ) + \frac{{σ}^{2}}{4 {E}_{b}} ( \frac{1}{2 N} {\sum }_{i ∈ K} {Z}_{i}^{2} )$$

using the soft decision or the absolute value quality index version of it

$${AverageSNR}_{a bs} ( 1 , K ) = StartSNR + \frac{1}{2} {Q}_{a bs} ( \{ {m}_{i} \} , K ) + \frac{{σ}^{2}}{4 {E}_{b}} ( \frac{1}{2 N} {\sum }_{i ∈ K} {Z}_{i}^{2} )$$

defining an absolute value quality index version, wherein StartSNR denotes the initial SNR value decoding without extrinsic information.

When K={0,1, . . . ,L−1} and N=L, these are the global quality indexes and the intrinsic SNR values previously described. However, when taken over a portion of a frame of data K={i,i+1, . . . ,i+N−1}, for 0≦i≦L−N−1 and N>0, then these quality indexes are essentially a moving average of extrinsic information, hereinafter defined as local quality indexes. Further, when K={0,1, . . . ,N−1}, with N=0,1, . . . ,L−1, then these local quality indexes reduce to the Yamamoto and Itoh type of indexes, Yamamoto et al., Viterbi Decoding Algorithm for Convolutional Codes with Repeat Request, IEEE Trans. Info. Theory, Vol 26, No 5, pp. 540-547, 1980, which is hereby incorporated by reference. Each type of these indexes has important practical applications in Automatic Repeat Request (ARQ) schemes wherein a radio communication device requests another (repeated) transmission of a portion of a frame of data that failed to be decoded properly, i.e. pass the quality index. In other words, if a receiver is not able to resolve (converge on) the data bits in time, the radio can request the transmitter to resend that portion of bits from the block, dependent on the decoding quality defined by the local quality indexes.

In practice, the present invention uses a local quality index and virtual SNR for convolutional decoding with extrinsic information input with K={0,1, . . . ,N−1}, 1≦N≦L as index set. As noted previously, the path metric improvement factor is

$$\frac{1}{2} {\sum }_{i = 0}^{L - 1} {m}_{i} {z}_{i}$$

Typically, the path metric difference without extrinsic information input is very small for low SNR. Therefore, this scaling factor can be used in a local quality index. For example, given that Y={y₀,t₀,y₁,t₁, . . . ,y_{L-1},t_{L-1}} denotes a whole frame of received samples and Z={z₀, z₁, . . . ,z_{L-1}} is the corresponding extrinsic information, a Viterbi, SOVA, max-log-MAP or log-MAP can be used as a decoding scheme. With Q_{index}*(1,N) denoting any of the above type of local quality indexes or the calculated virtual SNR values, and A denoting a threshold value, an ARQ scheme can be derived wherein for 1≦N≦L, if Q_{index}*(1,N)≧A, the decoding process continues. Otherwise, a retransmission of the block samples with time index K={0,1, . . . ,N−1} can be requested.

It can be shown that a local quality index

$${Q}^{*} ( \{ {m}_{i} \} , N ) = \frac{1}{N \sqrt{{E}_{b}}} {\sum }_{t = 0}^{N - 1} {m}_{i} {z}_{i}$$

with Viterbi or SOVA decoding results in an error probability per node of

$${( {p}_{e} \leq Q ( \sqrt{\frac{2 {d}_{f} {E}_{b}}{{N}_{0}}} \{ 1 + \frac{{N}_{0} A}{8 {d}_{f} {E}_{b}} \} ) \cdot {ⅇ}^{{d}_{f} {E}_{b} / {N}_{0}} \cdot T ( D ) \vert )}_{D = {ⅇ}^{- {E}_{b} / {N}_{0}}}$$

where d_{f} is free distance of the decoding trellis and T(D) is the generating function. Analogously

$${( {p}_{b} \leq Q ( \sqrt{\frac{2 {d}_{f} {E}_{b}}{{N}_{0}}} \{ 1 + \frac{{N}_{0} A}{8 {d}_{f} {E}_{b}} \} ) \cdot {ⅇ}^{{d}_{f} {E}_{b} / {N}_{0}} \cdot \frac{\partial T ( D , L , I )}{\partial I} \vert )}_{L = 1 , l = 1 , D = {ⅇ}^{- {E}_{b} / {N}_{0}}}$$

where p_{b} is the bit error probability and T(D,L,I) is the generating function with L denoting the length and I denoting the number of 1's in the signal sequence.

Applying the same scheme for max-log-MAP decoding obtains

Lⱼ⁽¹⁾≧Lⱼ⁽⁰⁾+A, if xⱼ*=+1 and 0≦j≦L−1

Lⱼ⁽¹⁾≦Lⱼ⁽⁰⁾−A, if xⱼ^{x}=−1 and 0≦j≦L−1

and applying log-MAP decoding with the same scheme obtains a bit error probability of

$${p}_{b}^{M} \leq {p}_{b} \leq Q ( \sqrt{\frac{2 {d}_{f} {E}_{b}}{{N}_{0}}} \{ 1 + \frac{a}{\sqrt{{E}_{b}}} \} ) \cdot {ⅇ}^{{d}_{f} {E}_{b} / {N}_{0}} \cdot \frac{\partial T ( D , L , I )}{\partial I} {\vert}_{L = 1 , I = 1 , D = {ⅇ}^{- {E}_{b} / {n}_{0}}}$$

which demonstrates that the bit error probability with MAP decoding is not greater (is bounded by) the bit error probability of Viterbi decoding. Moreover, the above inequalities demonstrate that the upper bound of error will be reduced with extrinsic information input. It is believed that the performance will be similar if other local quality indexes are used. These results demonstrate the improvement in decoding performance using the local quality indexes and the ARQ schemes of the present invention. Clearly, the local quality indexes can be generalized to any turbo decoding case with iteration stopping criteria.

Turbo decoding is just an iterative operation of some convolutional decoding schemes wherein the ARQ schemes of the present invention can be extended. The key operations needed are to monitor local quality indexes at each iteration stage with some associated thresholds. Assuming a turbo decoder lo designed with M full iteration cycles, for each of the 2M half iteration cycles, a SISO convolutional decoding is used, and the ARQ scheme of the present invention is applied. A local quality index is associated with each of the iteration stages. For 1≦N≦L, {Q_{index}*(1,N,iter)}ᵢₜₑᵣ₌₀^{2M-1} is defined as any of the previous local quality index or virtual SNR values calculated at the corresponding half iteration cycle. Preferably, a soft decision local quality index is used. With {A(iter)}ᵢₜₑᵣ₌₀^{2M-1} denoting threshold values, the following ARQ scheme is used for turbo decoding. For iter=0, . . . ,2M−1, the ARQ scheme is checked at each of the corresponding half iteration cycles. For 1≦N≦L, if Q_{index}*(1,N,iter)≧A(iter), then decoding process continues. Otherwise, the receiver requests retransmission of the block having time index K={0,1, . . . ,N−1}. At each constituent decoding pass the local quality index is checked against the predetermined threshold requirements which are chosen to balance the overhead for retransmission versus the improvement in error performance of the decoders.

Intuitively, many retransmissions could be needed due to the repeated check of thresholds. This will, of course, increase the decoding overhead and reduce the throughput. However, theoretical results show that data frames passing the repeated check will result in better BER performance.

In review, the present invention provides a decoder that dynamically terminates iteration calculations and provide retransmit criteria in the decoding of a received convolutionally coded signal using quality index criteria. The decoder includes a standard turbo decoder with two recursion processors connected in an iterative loop. One novel aspect of the invention is having at least one additional recursion processor coupled in parallel at the inputs of at least one of the recursion processors. Preferably, the at least one additional recursion processor is a Viterbi decoder, and the two recursion processors are soft-input, soft-output (SISO) decoders. More preferably, there are two additional processors coupled in parallel at the inputs of the two recursion processors, respectively. All of the recursion processors, including the additional processors, perform concurrent iterative calculations on the signal. The at least one additional recursion processor calculates a quality index of the signal for each iteration and directs a controller to terminates the iterations when the measure of the quality index exceeds a predetermined level or retransmit data when the signal quality prevents convergence.

The quality index is a summation of generated extrinsic information multiplied by a quantity extracted from the LLR information at each iteration. The quantity can be a hard decision of the LLR value or the LLR value itself. Alternatively, the quality index is an intrinsic signal-to-noise ratio of the signal calculated at each iteration. In particular, the intrinsic signal-to-noise ratio is a function of the quality index added to a summation of the square of the generated extrinsic information at each iteration. The intrinsic signal-to-noise ratio can be calculated using the quality index with the quantity being a hard decision of the LLR value, or the intrinsic signal-to-noise ratio is calculated using the quality index with the quantity being the LLR value. In practice, the measure of the quality index is a slope of the quality index taken over consecutive iterations.

Another novel aspect of the present invention is the use of a local quality index to provide a moving average of extrinsic information during the above iterations wherein, if the local quality index improves then decoding continues. However, if the moving average degrades the receiver asks for a retransmission of the pertinent portions of the block of samples.

The key advantages of the present invention are easy hardware implementation and flexibility of use. In particular, the present invention can be used to stop iteration or ask for retransmission at any SISO decoder, or the iteration can be stopped or retransmission requested at half cycles of decoding.

Once the quality index of the iterations exceed a preset level the iterations are stopped. Also, the iterations can be stopped once the interations pass a predetermined threshold to avoid any false indications. Alternately, a certain number of mandatory iterations can be imposed before the quality indexes are used as criteria for iteration stopping.

The local quality index is used as a retransmit criteria in an ARQ system to reduce error during poor channel conditions. The local quality index, uses a lower threshold (than the quality index threshold) for frame quality. If the local quality index is still below the threshold after a predetermined number of iterations, decoding can be stopped and a request sent for frame retransmission.

As should be recognized, the hardware needed to implement local quality indexes for iteration stopping is extremely simple. Since there are LLR and extrinsic information output in each constituent decoding stage, only a MAC (multiply and accumulate unit) is needed to calculate the soft index. Advantageously, the local quality indexes can be implemented with some simple attachment to the existing turbo decoders.

FIG. 11 shows a flow chart representing an ARQ method 100 in the decoding of a received convolutionally coded signal using local quality index criteria, in accordance with the present invention. A first step 102 is providing a turbo decoder with two recursion processors connected in an iterative loop, and at least one additional recursion processor coupled in parallel at the inputs of at least one of the recursion processors. All of the recursion processors concurrently performing iteration calculations on the signal. In a preferred embodiment, the at least one additional recursion processor is a Viterbi decoder, and the two recursion processors are soft-input, soft-output decoders. More preferably, two additional processors are coupled in parallel at the inputs of the two recursion processors, respectively.

A next step 104 is calculating a quality index of the signal in the at least one recursion processor for each iteration. In particular, the quality index is a summation of generated extrinsic information from the recursion processors multiplied by a quantity extracted from the LLR information of the recursion processors at each iteration. The quality index can be a hard value or a soft value. For the hard value, the quantity is a hard decision of the LLR value. For the soft value, the quantity is the LLR value itself. Optionally, the quality index is an intrinsic signal-to-noise ratio (SNR) of the signal calculated at each iteration. The intrinsic SNR is a function of an initial signal-to-noise ratio added to the quality index added to a summation of the square of the generated extrinsic information at each iteration. However, only the last two terms are useful for the quality index criteria. For this case, there are also hard and soft values for the intrinsic SNR, using the corresponding hard and soft decisions of the quality index just described. This step also includes calculating a local quality index in the same way as above. The local quality index is determined over a subset of the quality index range (e.g. samples 1 through N of the entire frame). The local quality index is related to a moving average of the extrinsic information of the decoders.

A next step 106 is comparing the local quality index to a predetermined threshold. If the local quality index is greater than or equal to the predetermined threshold then the iterations are allowed to continue. However, if the local quality index is lower than the threshold, then in step 108 those samples are requested to be retransmitted in an attempt to obtain a higher quality signal, and the sample counter is reset so that the iterations can be reset and restarted.

A next step 110 is terminating the iterations when the measure of the quality index exceeds a predetermined level being higher than the predetermined threshold. Preferably, the terminating step includes the measure of the quality index being a slope of the quality index over the iterations. In practice, the predetermined level is at a knee of the quality index curve approaching its asymptote. More specifically, the predetermined level is set at 0.03 dB of SNR. A next step 112 is providing an output derived from the soft output of the turbo decoder existing after the terminating step.

While specific components and functions of the turbo decoder for convolutional codes are described above, fewer or additional functions could be employed by one skilled in the art and be within the broad scope of the present invention. The invention should be limited only by the appended claims.

What is claimed is:

1. A method of terminating iteration calculations in the decoding of a received convolutionally coded signal using local quality index criteria, the method comprising the steps of:
providing a turbo decoder with two recursion processors connected in an iterative loop, and at least one additional recursion processor coupled in parallel at the inputs of at least one of the recursion processors, all of the recursion processors concurrently performing iteration calculations on the signal;
calculating a local quality index of a moving average of extrinsic information from the at least one recursion processor for each iteration over a portion of the signal;
comparing the local quality index to a predetermined threshold; and
when the local quality index is greater than or equal to the predetermined threshold, continuing iterations, and
when the local quality index is less than the predetermined threshold, requesting a retransmission of the portion of the signal, resetting a frame counter, and continuing at the calculating step.

2. The method of claim 1, wherein the first providing step includes the at least one additional recursion processor being a Viterbi decoder, and the two recursion processors are soft-input, soft-output decoders.

3. The method of claim 1, wherein the first providing step includes two additional processors being coupled in parallel at the inputs of the two recursion processors, respectively.

4. The method of claim 1, wherein the calculating step includes the local quality index being a summation of generated extrinsic information over a local portion of the signal multiplied by a quantity extracted from the LLR information at each iteration.

5. The method of claim 1, wherein the calculating step includes calculating a global quality index of the signal in the at least one recursion processor for each iteration over a frame of the signal, and further comprising the steps of
terminating the iterations when the measure of the global quality index exceeds a predetermined level being greater than the predetermined threshold; and
providing an output derived from a soft output of the turbo decoder existing after the terminating step.

6. The method of claim 1, wherein the calculating step includes the local quality index being a Yamamoto and Itoh type of index calculated at each iteration.

7. The method of claim 1, wherein the calculating step includes the local quality index being an intrinsic signal-to-noise ratio of the signal calculated at each iteration, the intrinsic signal-to-noise ratio being a function of the local quality index added to a summation of the square of the generated extrinsic information at each iteration.

8. A decoder that dynamically terminates iteration calculations in the decoding of a received convolutionally coded signal using local quality index criteria, the decoder comprising:
a turbo decoder with two recursion processors connected in an iterative loop;
at least one additional recursion processor coupled in parallel at the inputs of at least one of the recursion processors, all of the recursion processors perform concurrent iterative calculations on the signal, the at least one additional recursion processor calculates a local quality index of a moving average of extrinsic information for each iteration over a portion of the signal; and
a controller that terminates the iterations when the measure of the local quality index is less than a predetermined threshold, and requests a retransmission of the portion of the signal.

9. The decoder of claim 8, wherein the at least one additional recursion processor is a Viterbi decoder, and the two recursion processors are soft-input, soft-output decoders.

10. The decoder of claim 8, wherein the at least one additional recursion processor includes two additional processors being coupled in parallel at the inputs of the two recursion processors, respectively.

11. The decoder of claim 8, wherein the local quality index is a summation of generated extrinsic information over a local portion of the signal multiplied by a quantity extracted from the LLR information at each iteration.

12. The decoder of claim 8, wherein the controller also calculates a global quality index and terminates the iterations when the measure of the global quality index exceeds a predetermined level being greater than the predetermined threshold; and wherein the controller provides an output derived from a soft output of the turbo decoder.

13. The decoder of claim 8, wherein the local quality index is derived from a Yamamoto and Itoh type of index calculated at each iteration.

14. The decoder of claim 8, wherein the local quality index is an intrinsic signal-to-noise ratio of the signal calculated at each iteration, the intrinsic signal-to-noise ratio being a function of the quality index added to a summation of the square of the generated extrinsic information at each iteration.
